(19) United States
(12) Patent Application Publication
(10) Pub. No.: US 2019/0331142 A1
(43) Pub. Date: Oct. 31, 2019

(54) METHODS AND APPARATUS FOR COOLING AN ELECTRONIC DEVICE BY USING AN ELECTRO-OSMOTIC (EO) PUMP

(71) Applicant: QUALCOMM Incorporated, San Diego, CA (US)

(72) Inventors: Victor CHIRIAC, Phoenix, AZ (US); Jorge ROSALES, San Diego, CA (US); Jon James ANDERSON, Boulder, CO (US)

(21) Appl. No.: 15/967,500

(22) Filed: Apr. 30, 2018

(51) Int. Cl. F04F 99/00; H01L 23/427

(52) U.S. Cl. CPC F04F 99/00; H01L 23/427

(57) ABSTRACT

A device that includes an integrated device and a heat dissipating device coupled to the integrated device. The heat dissipating device includes an electro-osmotic (EO) pump. The electro-osmotic (EO) pump includes a casing comprising a first opening and a second opening; a membrane located in the casing; an anode electrode; a cathode electrode; and a catalyst layer formed on a surface of the membrane. The membrane includes a plurality of channels. The electro-osmotic (EO) pump is configured to provide a fluid to flow from the first opening of the casing, through the plurality of channels of the membrane and out of the second opening of the casing. The catalyst layer is configured to recombine gas ions that are produced by the electro-osmotic (EO) pump.

### BACKGROUND

### Field

Various features relate to an electro-osmotic (EO) pump, and more specifically to an electro-osmotic (EO) pump for heat dissipating technology for an electronic device, where the electro-osmotic (EO) pump catalyst provides improved fluid flow rate through enhanced recombination of gases.

### Background

Electronic devices include internal components that generate heat. Some of these internal components include a central processing unit (CPU), a graphics processing unit (GPU) and/or memory. Some of these internal components can generate a lot of heat. Specifically, a high performance CPU and/or GPU of an electronic device can generate a lot of heat, especially when performing data intensive operations (e.g., games, processing video).

To counter or dissipate the heat generated by the CPU and/or GPU, an electronic device may include a heat dissipating device, such as a heat spreader. However, a heat spreader is a passive heat dissipating device that has limited heat dissipating capabilities.

FIG. 1 illustrates an example of a heat dissipating device 100 that uses active thermal management. The heat dissipating device 100 uses external energy to power the pump 104 to increase heat dissipation. The heat dissipating device 100 includes a condenser 102, the pump 104, an evaporator 106, at least one conduit 110, and a fluid 120. The pump 104 is used to move the fluid 120, through the conduit 110, from the condenser 102 to the evaporator 106, where fluid 120 picks up heat (e.g., energy) from a heat generating source. The fluid 120 then flows through the conduit 110, back to the condenser 102, where heat in the fluid 120 is released through the condenser 102.

The upside of the heat dissipating device 100 is that with the pump 104, the heat dissipating device 100 is able to dissipate a lot more heat than a passive heat dissipating device of comparable size. However, the downside is that the pump 104 is a mechanical pump that has moving parts (e.g., piston, gears) that can make a lot of noise and vibration, which makes the mechanical pump not suitable for many devices and/or applications. In addition, pumps with moving parts do not last very long. Moreover, pumps with moving parts are very difficult to miniaturize due to the various moving parts, which means they are not suitable for small devices that require efficient heat dissipation. Another issue with pumps with moving parts is that they require a lot of energy to operate, which makes them not suitable for devices that can only store a limited amount of energy, such as mobile electronic devices.

Therefore, there is a need for an improved method and design for efficiently dissipating heat from an electronic device (e.g., mobile device), while at the same time keeping the size of the heat dissipating device small enough so that the heat dissipating device can be implemented in an electronic device (e.g., mobile device).

### SUMMARY

Various features relate to an electro-osmotic (EO) pump, and more specifically to an electro-osmotic (EO) pump for a heat dissipating device for an electronic device, where the electro-osmotic (EO) pump catalyst provides improved fluid flow rate through enhanced recombination of gases (through optimized catalyst placement).

One example provides a device that includes an integrated device and a heat dissipating device coupled to the integrated device. The heat dissipating device includes an electro-osmotic (EO) pump. The electro-osmotic (EO) pump includes a casing comprising a first opening and a second opening; a membrane located in the casing; an anode electrode; a cathode electrode; and a catalyst layer formed on a surface of the membrane or internal walls. The membrane includes a plurality of channels. The electro-osmotic (EO) pump is configured to provide a fluid to flow from the first opening of the casing, through the plurality of channels of the membrane and out of the second opening of the casing. The fluid is inducted to flow through the plurality of channels of the membrane through an electric field that is generated by the anode electrode and the cathode electrode. The catalyst layer is configured to recombine gas ions that are produced by the membrane.

Another example provides an apparatus that includes an integrated device and means for heat dissipation coupled to the integrated device. The means for heat dissipation includes means for electro-osmotic (EO) pumping. The means for electro-osmotic (EO) pumping includes a casing comprising a first opening and a second opening; a membrane located in the casing; an anode electrode; a cathode electrode; and a catalyst layer formed on a surface of the membrane. The membrane includes a plurality of channels. The means for electro-osmotic (EO) pumping is configured to provide a fluid to flow from the first opening of the casing, through the plurality of channels of the membrane and out of the second opening of the casing. The fluid is inducted to flow through the plurality of channels of the membrane through an electric field that is generated by the anode electrode and the cathode electrode. The catalyst layer is configured to recombine gas ions that are produced by the membrane.

### DRAWINGS

Various features, nature and advantages may become apparent from the detailed description set forth below when taken in conjunction with the drawings in which like reference characters identify correspondingly throughout.

FIG. 1 illustrates a heat dissipating device that uses a mechanical pump.

FIG. 2 illustrates a profile view of an electro-osmotic (EO) pump that can be implemented in a heat dissipating device.

FIG. 3 illustrates a cross sectional view of an exemplary membrane of an electro-osmotic (EO) pump.

FIG. 4 illustrates an angled view of an exemplary membrane of an electro-osmotic (EO) pump.

FIG. 5 illustrates a profile view of another electro-osmotic (EO) pump that can be implemented in a heat dissipating device.

FIG. 6 illustrates a cross sectional view of a membrane of an electro-osmotic (EO) pump.

FIG. 7 illustrates an angled view of a membrane of an electro-osmotic (EO) pump.

FIG. 8 illustrates a cross sectional view of a membrane of an electro-osmotic (EO) pump that includes a catalyst.

FIG. 9 illustrates an angled view of a membrane of an electro-osmotic (EO) pump that includes a catalyst.

FIG. 10 illustrates a view of a catalyst structure that can be implemented in an electro-osmotic (EO) pump.

FIG. 11 illustrates a view of another catalyst structure that can be implemented in an electro-osmotic (EO) pump.

FIG. 12 illustrates a profile view of another electro-osmotic (EO) pump that includes a catalyst structure, that can be implemented in a heat dissipating device.

FIG. 13 illustrates a profile view of another electro-osmotic (EO) pump that includes a catalyst structure, that can be implemented in a heat dissipating device.

FIG. 14 illustrates an exemplary flow diagram of a method for fabricating an electro-osmotic (EO) pump that be implemented in a heat dissipating device.

FIG. 15 illustrates various electronic devices that may integrate a pump, semiconductor device, an integrated device, a die, an integrated circuit, a PCB and/or a multi-layer heat spreader described herein.

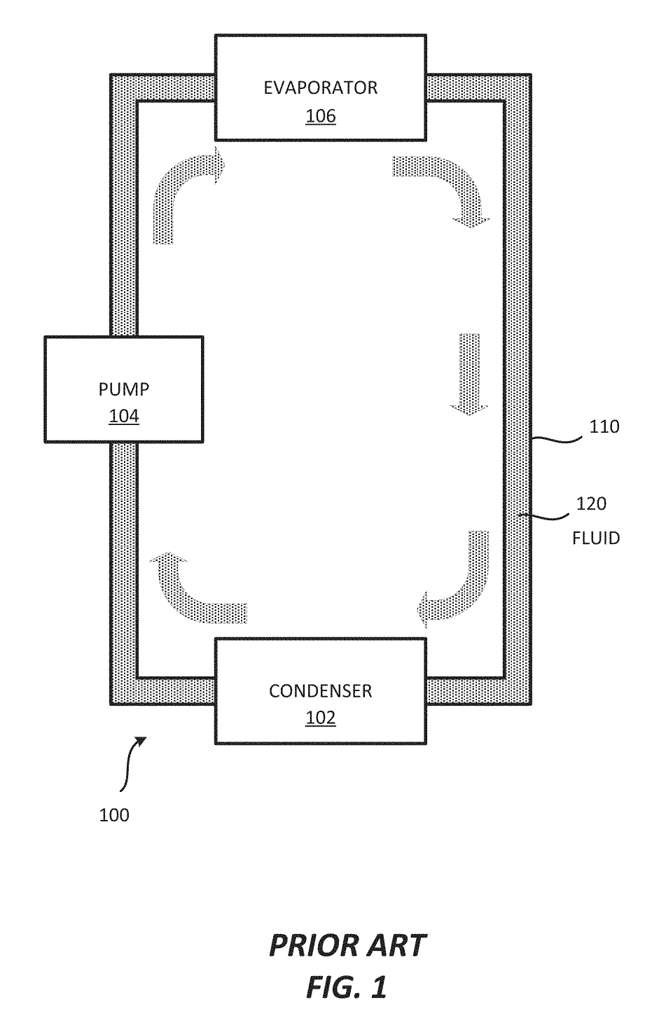

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may or may not be shown in block diagrams in order to avoid obscuring the aspects in unnecessary detail. In other instances, well-known circuits, structures and techniques may not be shown in detail in order not to obscure the aspects of the disclosure.

### Overview

Some implementations provide a device that includes an integrated device and a heat dissipating device coupled to the integrated device. The heat dissipating device (e.g., means for heat dissipation) includes an electro-osmotic (EO) pump (e.g., means for electro-osmotic (EO) pumping). The electro-osmotic (EO) pump includes a casing comprising a first opening and a second opening; a membrane located in the casing; an anode electrode; a cathode electrode, and a catalyst layer formed on a surface of the membrane or other internal walls. The membrane includes a plurality of channels. The electro-osmotic (EO) pump is configured to provide a fluid to flow from the first opening of the casing, through the plurality of channels of the membrane and out of the second opening of the casing. The fluid is inducted to flow through the plurality of channels of the membrane through an electric field that is generated by the anode electrode and the cathode electrode. The catalyst layer is configured to recombine gas ions that are produced by the electro-osmotic (EO) pump (e.g., membrane).

### Exemplary Electro-Osmotic (EO) Pump for Heat Dissipating Device

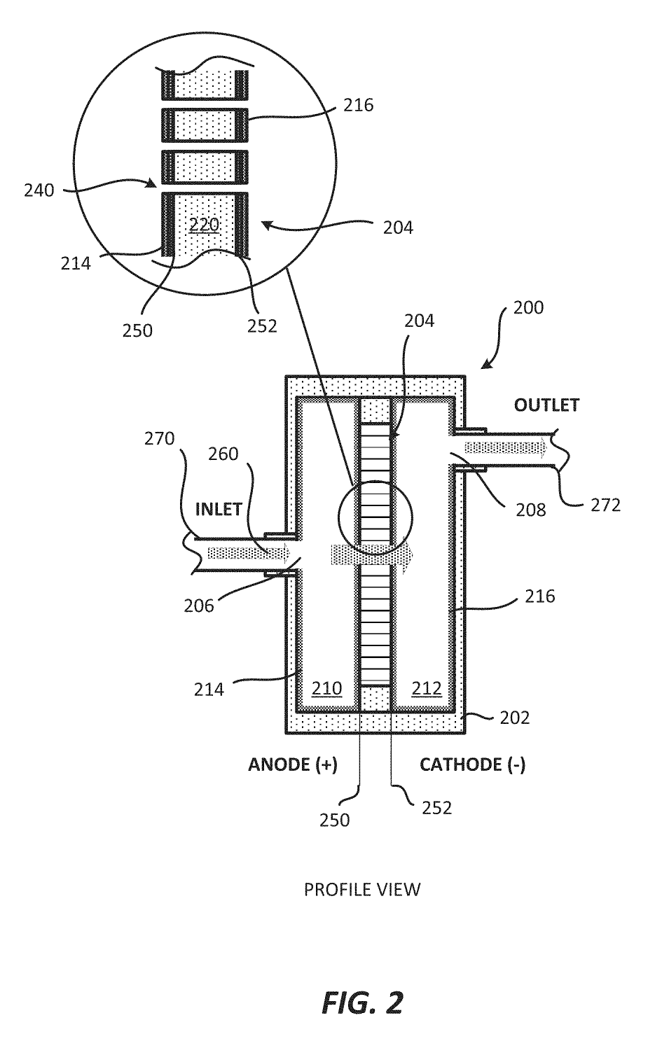

FIG. 2 illustrates an electro-osmotic (EO) pump 200 that can be implemented in a heat dissipating device (e.g., means for heat dissipating) for an electronic device (e.g., mobile device). For example, the electro-osmotic (EO) pump 200 may be implemented with a conduit (e.g., pipe) that circulates a fluid inside the electronic device. The electro-osmotic (EO) pump 200 may also be used with a conduit, an evaporator, and a condenser. The electro-osmotic (EO) pump 200 allows fluid to travel in a direction that is opposite to gravity. Thus, irrespective of how the electro-osmotic (EO) pump 200 or a device that includes the electro-osmotic (EO) pump 200, is oriented, fluid will flow through the electro-osmotic (EO) pump 200.

The electro-osmotic (EO) pump 200 (e.g., means for electro-osmotic (EO) pumping) includes a casing 202, a membrane 204, a first opening 206, a second opening 208, a first chamber 210, a second chamber 212, a first catalyst layer 214, a second catalyst layer 216, a first electrode 250, and a second electrode 252.

The membrane 204 is located in the casing 202. The membrane 204 includes a membrane material 220. The membrane 204 includes a plurality of channels 240 that travels through the membrane material 220. The plurality of channels 240 allows a fluid 260 to travel through the membrane 204. The first electrode 250 is located on a first side of the membrane 204, and the second electrode 252 is located on a second side of the membrane 204. The first electrode 250 may be located on a first surface of the membrane 204 and/or embedded in the first side of the membrane 204. The second electrode 252 may be located on a second surface of the membrane 204 and/or embedded in the second side of the membrane 204. The second surface may be opposite to the first surface. The first electrode 250 and the second electrode 252 may include an electrically conductive material. The first electrode 250 and the second electrode 252 may be considered part of the membrane 204 or separate from the membrane 204.

In some implementations, the first electrode 250 is configured as an anode electrode, and the second electrode 252 is configured as a cathode electrode through a voltage that is provided to the first electrode 250 and the second electrode 252. However, the first electrode 250 may configured as a cathode electrode, and the second electrode 252 may be configured as an anode electrode through a voltage that is provided to the first electrode 250 and the second electrode 252. The first electrode 250 and the second electrode 252 may be coupled to interconnects that are coupled to a voltage source and/or a power source.

The first chamber 210 is a space in the casing 202 that is defined by the inner walls of the casing 202 and the membrane 204. The second chamber 212 is a space in the casing 202 that is defined by the inner walls of the casing 202 and the membrane 204. A first catalyst layer 214 is formed over the walls (e.g., some or all of the walls) of the first chamber 210 and/or a first surface of the membrane 204. In some implementations, the first catalyst layer 214 may be formed only over the first surface of the membrane 204. A second catalyst layer 216 is formed over the walls (e.g., some or all of the walls) of the second chamber 212 and/or a second surface of the membrane 204. In some implementations, the second catalyst layer 216 may be formed only over the second surface of the membrane 204. The catalyst layer(s) may be deposited and/or coated on the wall(s) of the chamber(s) and/or the surface(s) of the membrane. The first chamber 210 and/or the second chamber 212 may have similar or different shapes and/or sizes; and/or inner walls with similar or different shapes and/or sizes.

When water (e.g., H₂O) is the fluid used with the electro-osmotic (EO) pump 200, the process of inducing fluid flow through the plurality of channels 240 of the membrane 204 creates gas ions, such as Oxygen and/or Hydrogen. For example, water that is near and/or comes in contact with the frit material (e.g., membrane, membrane material) may cause Oxygen and Hydrogen ions to be formed. In some implementations, the first catalyst layer 214 and the second catalyst layer 216 may be used to help recombine these gas ions so they become a liquid again (e.g., water). As mentioned above, recombination helps improve the flow rate of the fluid, which in turns helps increase heat dissipation.

Fluid flow can be induced by the electro-osmotic (EO) pump 200, by providing a voltage to the first electrode 250 and/or the second electrode 252. When a positive voltage (+) is provided to the first electrode 250, the first electrode 250 becomes an anode electrode, and the second electrode 252 becomes a cathode electrode. In addition, an electric field is created between the first electrode 250 and the second electrode 252. This electric field induces positive ions of the fluid (e.g., water) to moves towards the second electrode 252, resulting in fluid flow. The direction of the fluid flow through the electro-osmotic (EO) pump 200 can be reversed by applying a positive voltage (+) to the second electrode 252. This results in the second electrode 252 being an anode electrode and the first electrode 250 being a cathode electrode.

In some implementations, a fluid 260 enters the electro-osmotic (EO) pump 200 from the inlet conduit 270 through the first opening 206 and into the first chamber 210. The fluid 260 would then travel through the plurality of channels 240 of the membrane 204 (e.g., through the plurality of channels 240 of the membrane material 220) and to the second chamber 212. As the fluid 260 travels the plurality of channels 240, gases such as Oxygen and/or Hydrogen may be formed in the first chamber 210 and/or the second chamber 212. The gases (e.g., gas ions) may be formed as a result of contact with or being near the frit material (e.g., membrane, membrane material). The fluid 260 travels from the second chamber 212 to the second opening 208 and to the outlet conduit 272. At some point, the fluid 260 flows towards the inlet conduit 270. Between the outlet conduit 272 and the inlet conduit 270, the fluid 260 may travel through an evaporator and/or a condenser.

Over time, more and more gases will accumulate in the chambers and ultimately in the conduits if no catalyst material exists. This can lead to failure or greatly reduced performance of the electro-osmotic (EO) pump 200 and the heat dissipating device, since the electro-osmotic (EO) pump 200 is not designed to induce flow of gases. To prevent gases from accumulating in the electro-osmotic (EO) pump 200 and conduits (e.g., 270, 272), catalysts are used to help recombine gas ions back into a liquid. These catalysts are formed (e.g., coated, deposited) in the electro-osmotic (EO) pump 200 near where the gases are formed or where gases may be located. These catalysts help recombine the gases (e.g., O₂, H₂) into a liquid (e.g., water), thus preventing an accumulation of the gases (e.g., gas ions) in the electro-osmotic (EO) pump 200. The recombination of the gases also helps increase the flow rate of the fluid 260, and thus also helps increase the heat dissipating capabilities of heat dissipating device that includes the electro-osmotic (EO) pump 200. The present disclose provides several implementations that include catalyst layers and/or catalyst structures in various locations to help with the recombination of gases (e.g., gas ions), which helps improve the flow rate of the fluid, and in turn improves the heat dissipating capabilities of the heat dissipating device. The locations, positions, and/or designs of the catalyst layers and/or catalyst structures described in the disclosure help optimize and maximize the recombination.

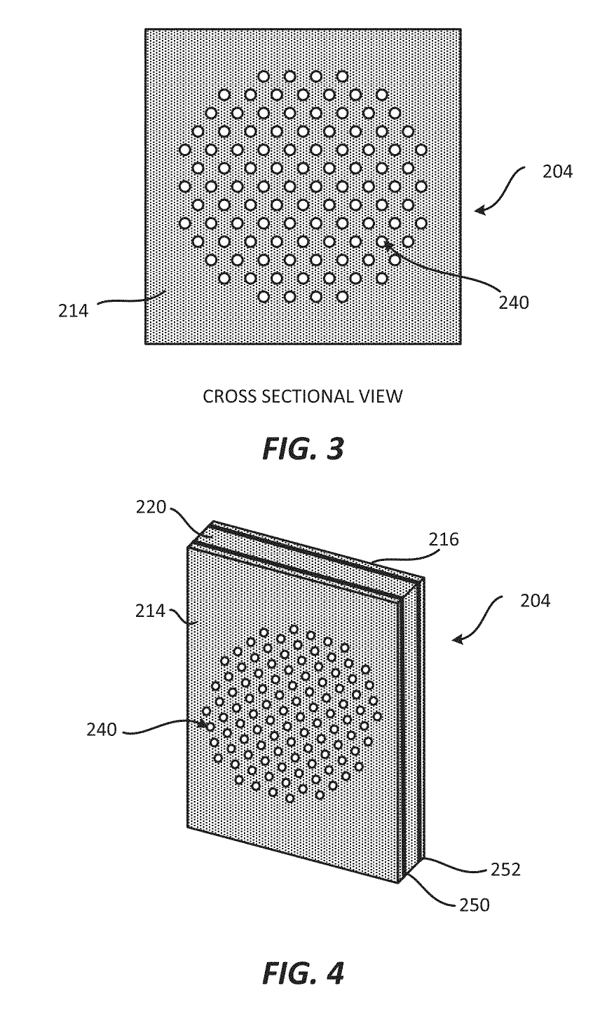

FIGS. 3 and 4 illustrate views of the membrane 204. FIGS. 3 and 4 illustrate that the membrane 204 include the plurality of channels 240. The first catalyst layer 214 is formed over the membrane 204. For example, the first catalyst layer 214 may be formed over a first surface of the membrane material 220 and/or the first electrode 250. The first electrode 250 may be located between the membrane material 220 and the first catalyst layer 214. The first electrode 250 may be embedded in the membrane material 220.

The second catalyst layer 216 is formed over the membrane 204. For example, the second catalyst layer 216 may be formed over a second surface of the membrane material 220 and/or the second electrode 252. The second electrode 252 may be located between the membrane material 220 and the second catalyst layer 216. The second electrode 252 may be embedded in the membrane material 220.

The plurality of channels 240 are formed such that they create a functional lateral surface area that is circular or approximately circular. It is noted that different implementations may form the plurality of channels 240 in the membrane 204 to have different functional lateral surface areas or sizes. For example, the functional lateral surface area may have a rectangular shape, a square shape, an oval shape, etc. . . . .

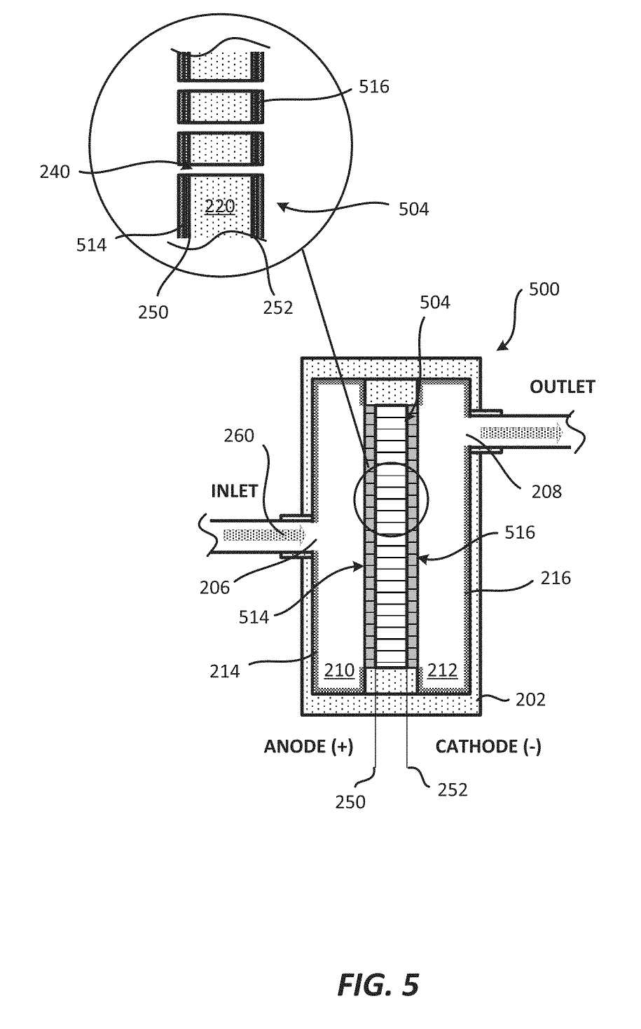

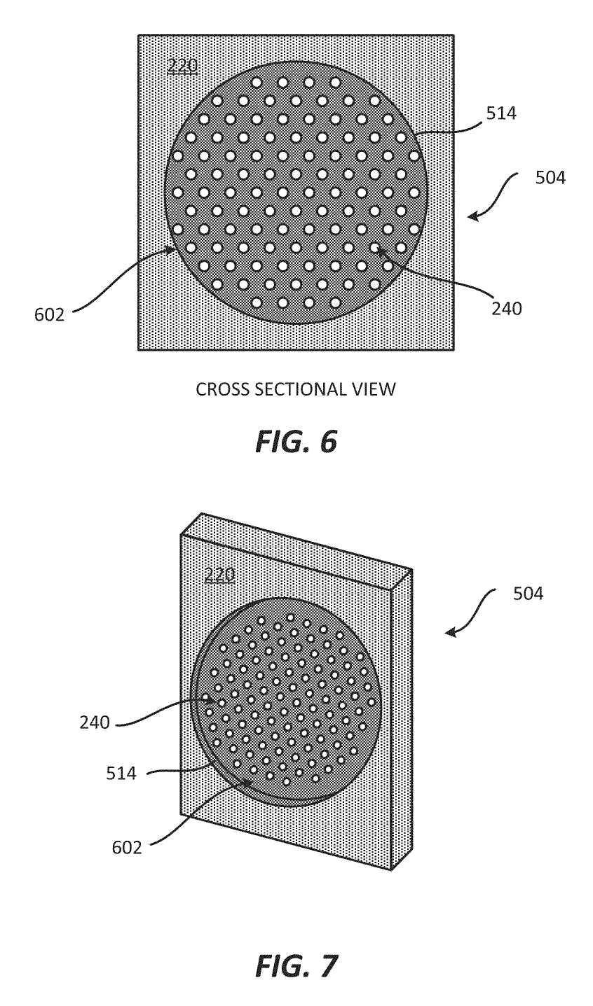

FIG. 5 illustrates another electro-osmotic (EO) pump 500. The electro-osmotic (EO) pump 500 is similar to the electro-osmotic (EO) pump 200. The electro-osmotic (EO) pump 500 (e.g., means for electro-osmotic (EO) pumping) includes a membrane 504 that has a different design. FIGS. 6 and 7 illustrate views of the membrane 504. The membrane 504 includes the membrane material 220 and a recessed cavity 602. The first catalyst layer 514 is formed over the walls of the recessed cavity 602. The plurality of channels 240 travels through the membrane material 220. The recessed cavity 602 may define a functional lateral surface area for the electro-osmotic (EO) pump 500. A similar recessed cavity may be formed on the opposite side of the membrane material 220. A second catalyst layer 516 may be formed on the walls of the other recessed cavity. In some implementations, the walls of the first chamber 210 may be partially or fully coated with the first catalyst layer 214, or free of coating of the first catalyst layer 214. Similarly, the walls of the second chamber 212 may be partially or fully coated with the second catalyst layer 216, or free of coating of the second catalyst layer 216.

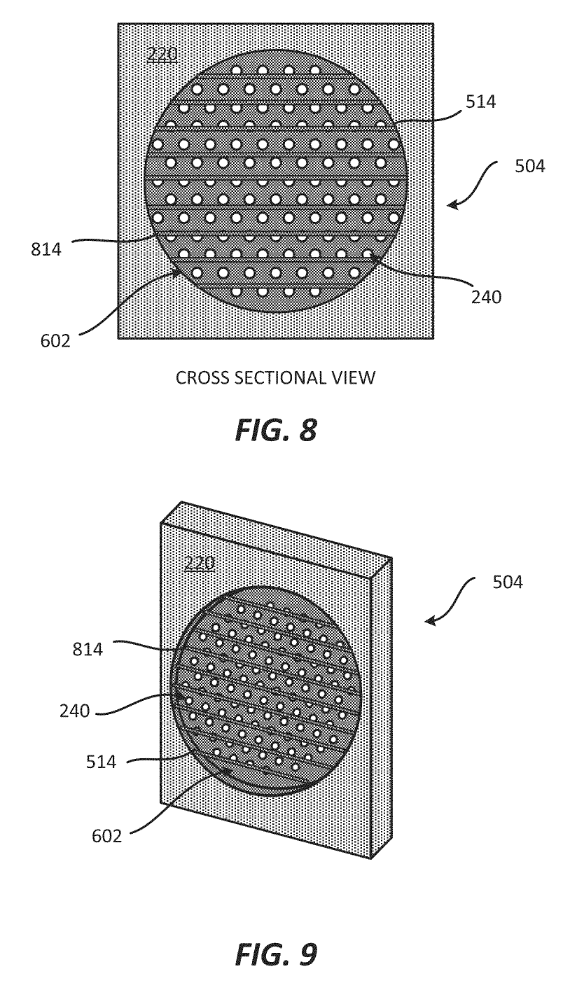

FIGS. 8 and 9 illustrate a catalyst structure 814 formed in the recessed cavity 602. The catalyst structure 814 is configured as vents for the recessed cavity 602. The catalyst structure 814 may include panels that the fluid can travel in between. The panels may have different shapes (e.g., cylindrical, wing, rectangular). The catalyst structure 814 may have different number of panels. The panels may be approximately perpendicular to the surface of the membrane 204. The panels may be vertical, horizontal, orthogonal, diagonal, or combinations thereof. There may be a space between the panels of the catalyst structure 814 and the plurality of channels 240 to allow the fluid to flow through. The first catalyst layer 514 may be part of the catalyst structure 814. The catalyst structure 814 may be part of the first catalyst layer 514. A similar catalyst structure may be formed on another recessed cavity of the membrane 504. Thus, the membrane 204 may include a first catalyst structure and a second catalyst structure.

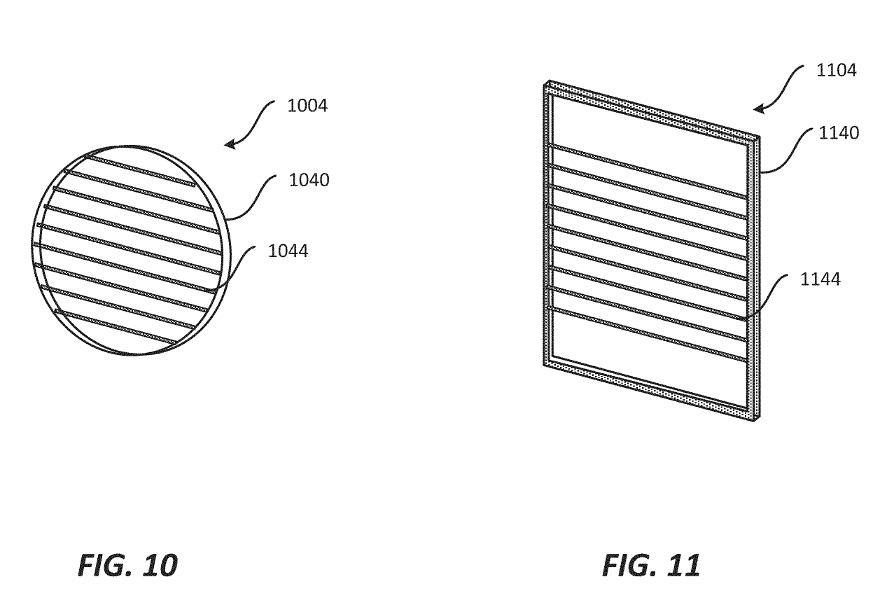

FIGS. 10 and 11 illustrate examples of catalyst structures. The catalyst structure 1004 includes a frame 1040 and a plurality of vents 1044. The frame 1040 and/or the plurality of vents 1044 include a catalyst material. The catalyst structure 1004 has a circular shape. The catalyst structure 1104 includes a frame 1140 and a plurality of vents 1144. The frame 1140 and/or the plurality of vents 1144 include a catalyst material. The catalyst structure 1104 has a square shape. It is noted that the catalyst structures may have different shapes. The plurality of vents 1044 and 1144 may be vertical, horizontal, orthogonal, diagonal, or combinations thereof. The plurality of vents 1044 and 1144 may be arranged at different angles.

The catalyst structures 1004 and/or 1104 may be implemented in the recessed cavity of the membrane (e.g., 204, 504) and/or the chamber (e.g., 210, 212) of the electro-osmotic (EO) pump 200.

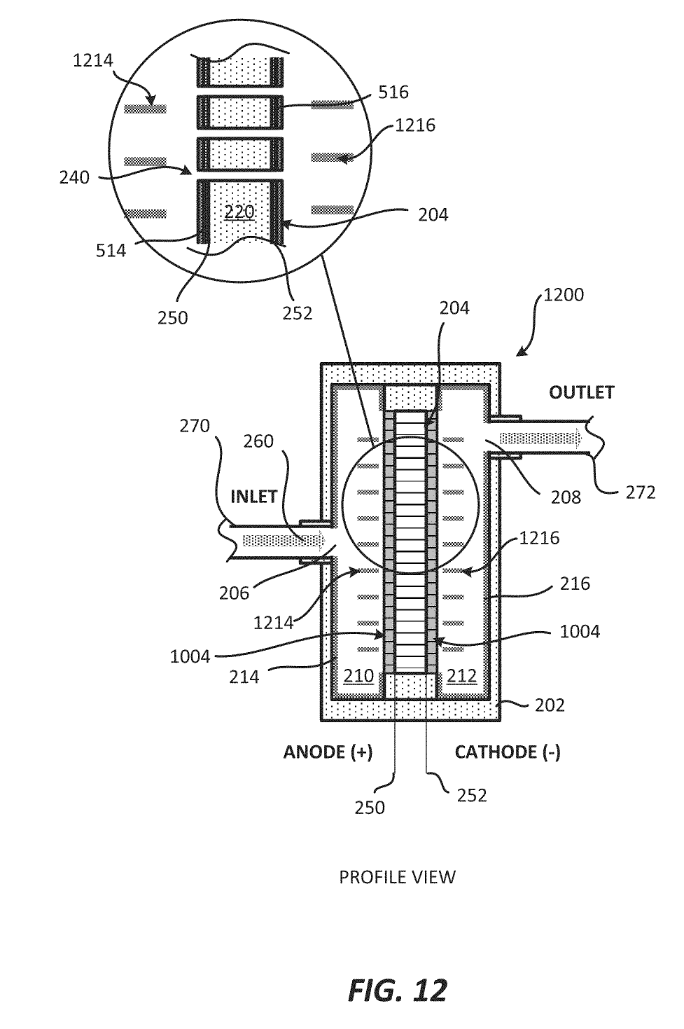

FIG. 12 illustrates another electro-osmotic (EO) pump 1200. The electro-osmotic (EO) pump 1200 is similar to the electro-osmotic (EO) pump 500. The electro-osmotic (EO) pump 1200 (e.g., means for electro-osmotic (EO) pumping) includes a first catalyst structure 1214 and a second catalyst structure 1216. The first catalyst structure 1214 is located in the first chamber 210, and the second catalyst structure 1216 is located in the second chamber 212. The first catalyst structure 1214 includes a first plurality of vents. The second catalyst structure 1216 includes a second plurality of vents. The first and second plurality of vents are approximately perpendicular to the surface of the membrane 204. The plurality of vents may be vertically aligned, horizontally aligned, diagonally aligned, and/or combination thereof. The first catalyst structure 1214 and/or the second catalyst structure 1216 may be the catalyst structure 1004 and/or the catalyst structure 1104.

In some implementations, the walls of the first chamber 210 may be partially or fully coated with the first catalyst layer 214, or free of coating of the first catalyst layer 214. Similarly, the walls of the second chamber 212 may be partially or fully coated with the second catalyst layer 216, or free of coating of the second catalyst layer 216. In some implementations, the electro-osmotic (EO) pump 1200 may include a catalyst structure (e.g., 814, 1004, 1104) in recessed portion(s) of the membrane 204.

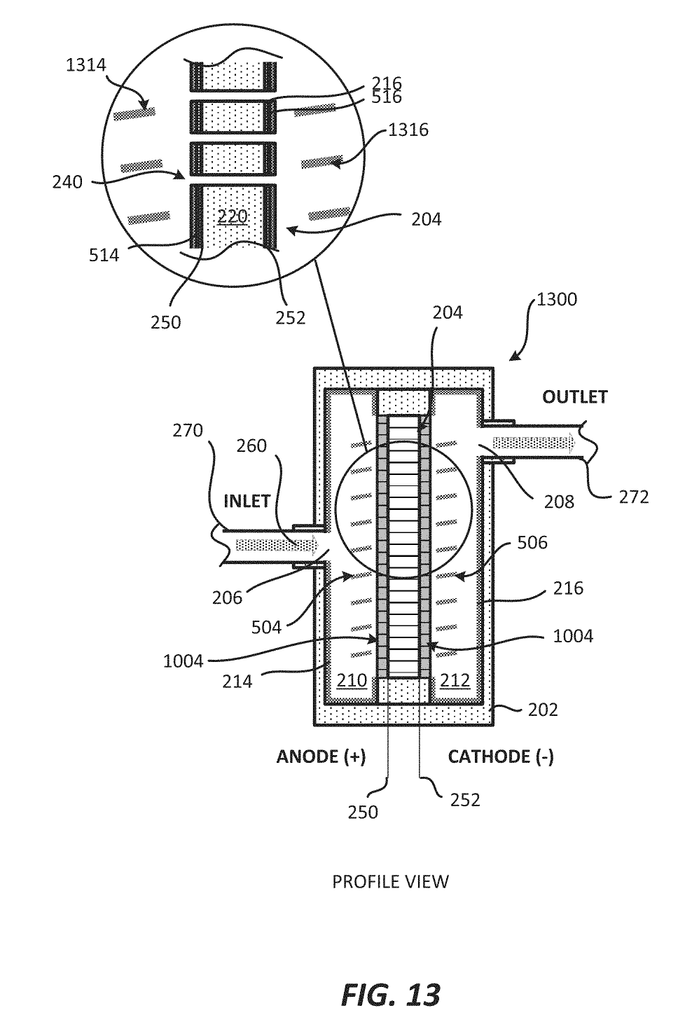

FIG. 13 illustrates another electro-osmotic (EO) pump 1300. The electro-osmotic (EO) pump 1300 is similar to the electro-osmotic (EO) pump 1200. The electro-osmotic (EO) pump 1300 (e.g., means for electro-osmotic (EO) pumping) includes a first catalyst structure 1314 and a second catalyst structure 1316. The first catalyst structure 1314 is located in the first chamber 210, and the second catalyst structure 1316 is located in the second chamber 212. The first catalyst structure 1314 includes a first plurality of vents. The second catalyst structure 1316 includes a second plurality of vents. The first and second plurality of vents are non-perpendicular to the surface of the membrane 204. Different vents may be arranged at different angles relative to the surface of the membrane 204. The plurality of vents may be vertically aligned, horizontally aligned, diagonally aligned, and/or combination thereof. The first catalyst structure 1314 and/or the second catalyst structure 1316 may be the catalyst structure 1004 and/or the catalyst structure 1104. In some implementations, the walls of the first chamber 210 may be partially or fully coated with the first catalyst layer 214. Similarly, the walls of the second chamber 212 may be partially or fully coated with the second catalyst layer 216. In some implementations, the electro-osmotic (EO) pump 1300 may include a catalyst structure (e.g., 814, 1004, 1104) in recessed portion(s) of the membrane 204. It is noted that recessed portions or cavities may have different shapes and sizes. Different implementations may have different numbers of recessed portions or cavities. In some implementations, there is no recessed portion.

Different implementations may use different materials for the different components of the electro-osmotic (EO) pump. In addition, different implementations may use different shapes and dimensions for the different features of the electro-osmotic (EO) pump. Examples of the different materials and different designs that can be used are further described below.

### Exemplary Materials, Dimensions and Designs

The membrane 204 may include porous materials and/or non-porous materials. In some implementations, a porous material is a material that allows a fluid to easily pass through it. When the membrane 204 includes a porous material, fluid may flow through the membrane through the plurality of channels and/or other portions of the membrane. The membrane material 220 may include a dielectric, a glass, ceramic, metal, and/or combinations thereof. The catalyst layer and/or the catalyst structure may include Teflon, platinum, and/or combinations thereof.

The use of a plurality of channels 240 helps with the fluid flow. The plurality of channels 240 may represent some or all of the channels that travel through the membrane material 220 and/or the membrane 204. The plurality of channels 240 may have different cross-sectional shapes and sizes. In some implementations, the plurality of channels 240 may have a cross section that has a circular shape and/or a rectangular shape. One or more channels of the plurality of channels 240 may have a diameter and/or a width of about 0.5-2 micrometers (μm). In some implementations, the term diameter may represent the width and/or length of the opening of the channel. In some implementations, one or more channels of the plurality of channels 240 may have a diameter and/or a width of about 1 micrometer (μm) or less (e.g., 0.5-1 micrometers (μm)). The diameter of the channel cannot be too large since it would make the electro-osmotic (EO) pump less efficient. Thus, the narrower the diameter of the channels the better the performance of the pump. The membrane 204 may have a thickness in a range of about 100-500 micrometers (μm). In some implementations, the length of the plurality of channels 240 may be in a range of about 100-500 micrometers (μm). In some implementations, increasing the thickness of the membrane reduces the driving electric field and thus the flow rate.

The number of plurality of channels 240 will vary based on how much heat dissipating capabilities is desired. The number of plurality of channels 240 may form a cross sectional area that can be described as the functional lateral surface area of the electro-osmotic (EO) pump. The functional lateral surface area may be a total and/or effective area that the fluid can travel through the membrane 204. In some implementations, the electro-osmotic (EO) pump may have a functional lateral surface area in a range of about 2-8 centimeters squared (cm²). For example, in some implementations, the combine areas of the opening of the plurality of channels 240 may be in a range of about 2-8 centimeters squared (cm²). The larger the functional lateral surface area the better the flow rate. The voltage that is applied to the electrodes may be in a range of about 2-6 Volts (V). The higher the voltage, the higher the strength of the driving electric field, thus the better the flow rate of the fluid.

In some implementations, the electro-osmotic (EO) pump 200 provides a flow rate of about 1 milliliter (mL)/minute or greater, which can translate to about 8-10 Watts (W) of cooling capabilities. In some implementations, the electro-osmotic (EO) pump 200 may require about 8 milliWatts (mW) of power to run the pump (e.g., to provide voltage to the electrodes), but the electro-osmotic (EO) pump 200 provides about 8-10 Watts (W) of cooling capabilities. All of this while the whole heat dissipating device is implemented in an electronic device (e.g., mobile device). The use of the materials and the design of the heat dissipating device in the present disclosure allows for effective and efficient heat transfer or heat removal from a heat generating region of a device.

### Exemplary Method for Fabricating an Electro-Osmotic (EO) Pump

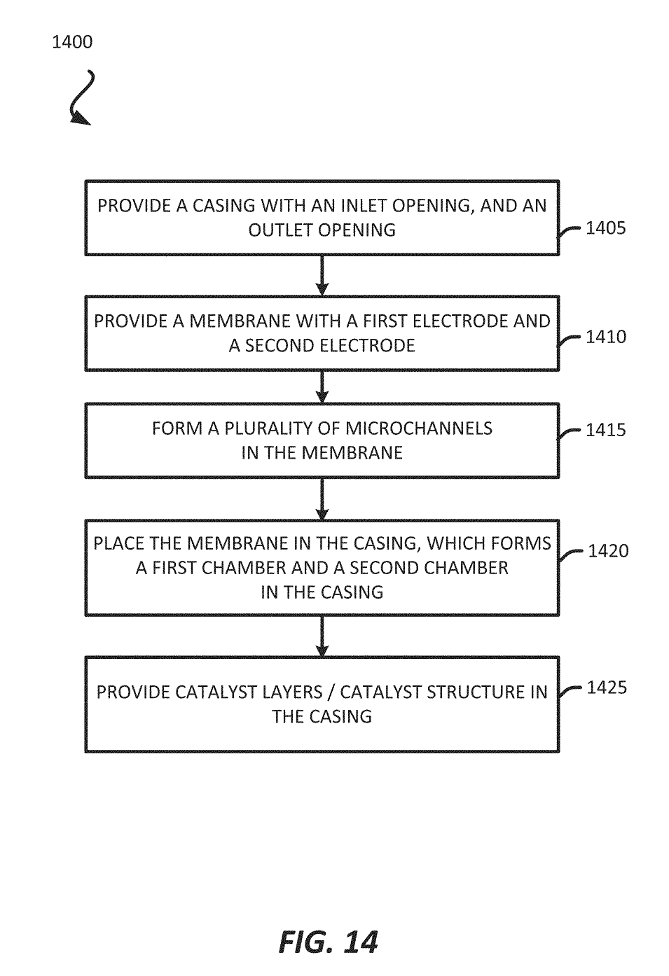

FIG. 14 illustrates a flow chart of an exemplary method 1400 for fabricating an electro-osmotic (EO) pump. The method of FIG. 14 may be used to fabricate any of the electro-osmotic (EO) pumps described in the present disclosure. It is noted the order of the method may be changed and/or modified. In some implementations, some of the processes may be formed concurrently. In some implementations, all of the components described below may be formed from one part and/or material.

The method 1400 for fabricating the electro-osmotic (EO) pump may be performed before, concurrently, or after the device (e.g., mobile) is assembled. For example, the device (e.g., mobile device) may be assembled to include a region, an integrated device may be provided in the region of the device, and the heat dissipating device comprising the electro-osmotic (EO) pump may be fabricated and coupled to the region that includes the integrated device.

As shown in FIG. 14, the method provides (at 1405) a casing 202 that includes a first opening 206 and a second opening 208. The first opening 206 may be an inlet opening, and the second opening 208 may be an outlet opening.

The method provides (at 1410) a membrane 204 with a first electrode 250 and a second electrode 252. The membrane 204 may include a membrane material 220. The first electrode 250 and the second electrode 252 may be formed over surfaces of the membrane 204 and/or embedded in the membrane 204.

The method forms (at 1415) a plurality of channels 240 in the membrane 204. Different implementations may use channels with different sizes and shapes.

The method places (at 1420) the membrane 204 in the casing 202, which forms a first chamber 210 and a second chamber 212. An adhesive may be used to hold the membrane 204 in the casing 202.

The method provides (at 1425) a catalyst layer and/or a catalyst structure in the casing 202. The catalyst layer may be formed in the inner walls of the casing 202 and/or one or more surfaces of the membrane 204.

### Exemplary Electronic Devices

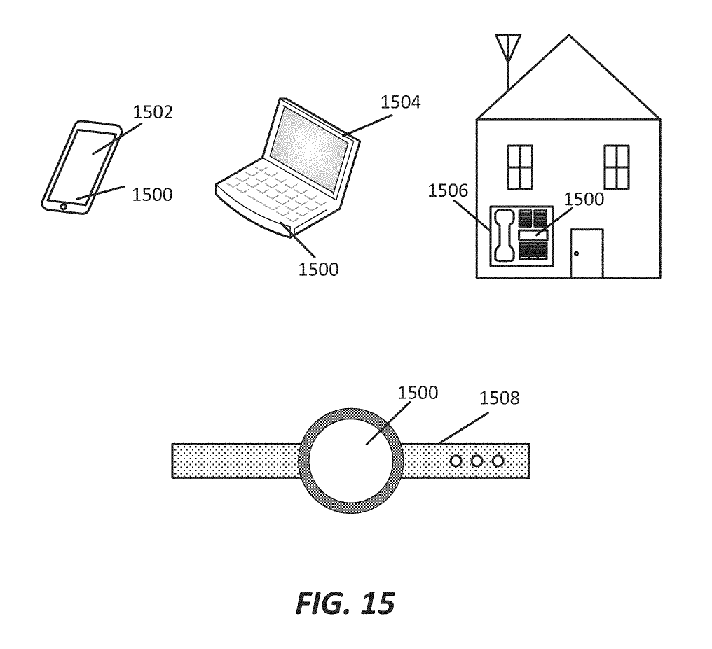

FIG. 15 illustrates various electronic devices that may be integrated with any of the aforementioned pump, heat dissipating device, integrated device, semiconductor device, integrated circuit, die, interposer, package or package-on-package (PoP). For example, a mobile phone device 1502, a laptop computer device 1504, a fixed location terminal device 1506, a wearable device 1508 may include an integrated device 1500 and/or heat dissipating device, as described herein. The integrated device 1500 may be, for example, any of the integrated circuits, dies, integrated devices, integrated device packages, integrated circuit devices, device packages, integrated circuit (IC) packages, package-on-package devices described herein. The devices 1502, 1504, 1506, 1508 illustrated in FIG. 15 are merely exemplary. Other electronic devices may also feature the integrated device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-15 may be rearranged and/or combined into a single component, process, feature or function or embodied in several components, proceses, or functions. Additional elements, components, processes, and/or functions may also be added without departing from the disclosure. It should also be noted that FIGS. 2-15 and its corresponding description in the present disclosure is not limited to be implemented with a specific dies and/or ICs. In some implementations, FIGS. 2-15 and its corresponding description may be used to manufacture, create, provide, and/or produce pump and heat dissipating device that are implemented with integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “about ‘value X’”, or “approximately”, as used in the disclosure shall mean within 10 percent of the ‘value X’. For example, a value of about 1 or approximately 1, would mean a value in a range of 0.9-1.1.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
an integrated device; and
a heat dissipating device coupled to the integrated device, the heat dissipating device comprising an electro-osmotic (EO) pump, the electro-osmotic (EO) pump comprising:
a casing comprising a first opening and a second opening;
a membrane located in the casing, the membrane comprising a plurality of channels;
an anode electrode;
a cathode electrode; and
a catalyst layer formed on a surface of the membrane,
wherein the electro-osmotic (EO) pump is configured to provide a fluid to flow from the first opening of the casing, through the plurality of channels of the membrane and out of the second opening of the casing,
wherein the fluid is inducted to flow through the plurality of channels of the membrane through an electric field that is generated by the anode electrode and the cathode electrode,
wherein the catalyst layer is configured to recombine gas ions that are produced by the electro-osmotic (EO) pump.

2. The device of claim 1, wherein the electro-osmotic (EO) pump allows fluid to flow in a direction opposite to gravity.

3. The device of claim 1, wherein the catalyst layer comprises Teflon, platinum, and/or combination thereof.

4. The device of claim 1, wherein an input of about 8 milliWatts (mW) of power to the electro-osmotic (EO) pump allows the electro-osmotic (EO) pump to provide about 8-10 Watts (W) of heat dissipation.

5. The device of claim 1, wherein the electro-osmotic (EO) pump comprises a functional lateral surface area in a range of about 2-8 centimeters squared (cm²).

6. The device of claim 1, wherein each channel from the plurality of channels comprises a diameter of about 0.5-2 micrometers (μm).

7. The device of claim 1, wherein the electro-osmotic (EO) pump further comprises:
a first chamber coupled to the membrane; and
a second chamber coupled to the membrane such that the membrane is located between the second chamber and the first chamber,
wherein the fluid is inducted to flow from first opening, through the first chamber, through the plurality of channels of the membrane, through the second chamber, and to the second opening.

8. The device of claim 7, wherein at least one wall of the first chamber comprises a catalyst layer.

9. The device of claim 7, wherein the first chamber comprises a catalyst structure comprising at least one vent.

10. The device of claim 1, wherein the electro-osmotic (EO) pump is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

11. An apparatus comprising:
an integrated device; and
means for heat dissipation coupled to the integrated device, the means for heat dissipation comprising means for electro-osmotic (EO) pumping, the means for electro-osmotic (EO) pumping comprising:
a casing comprising a first opening and a second opening;
a membrane located in the casing, the membrane comprising a plurality of channels;
an anode electrode;
a cathode electrode; and
a catalyst layer formed on a surface of the membrane,
wherein the means for electro-osmotic (EO) pumping is configured to provide a fluid to flow from the first opening of the casing, through the plurality of channels of the membrane and out of the second opening of the casing,
wherein the fluid is inducted to flow through the plurality of channels of the membrane through an electric field that is generated by the anode electrode and the cathode electrode,
wherein the catalyst layer is configured to recombine gas ions that are produced by the means for electro-osmotic (EO) pumping.

12. The apparatus of claim 11, wherein the means for electro-osmotic (EO) pumping allows fluid to flow in a direction opposite to gravity.

13. The apparatus of claim 11, wherein the catalyst layer comprises Teflon, platinum, and/or combination thereof.

14. The apparatus of claim 11, wherein an input of about 8 milliWatts (mW) of power to the means for electro-osmotic (EO) pumping allows the means for electro-osmotic (EO) pumping to provide about 8-10 Watts (W) of heat dissipation.

15. The apparatus of claim 11, wherein the means for electro-osmotic (EO) pumping comprises a functional lateral surface area in a range of about 2-8 centimeters squared (cm²).

16. The apparatus of claim 11, wherein each channel from the plurality of channels comprises a diameter of about 0.5-2 micrometers (μm).

17. The apparatus of claim 11, wherein the means for electro-osmotic (EO) pumping further comprises:
a first chamber coupled to the membrane; and
a second chamber coupled to the membrane such that the membrane is located between the second chamber and the first chamber,
wherein the fluid is inducted to flow from first opening, through the first chamber, through the plurality of channels of the membrane, through the second chamber, and to the second opening.

18. The apparatus of claim 17, wherein at least one wall of the first chamber comprises a catalyst layer.

19. The apparatus of claim 17, wherein the first chamber comprises a catalyst structure comprising at least one vent.

20. The apparatus of claim 1, wherein the means for electro-osmotic (EO) pumping is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
